(19) United States
(12) Patent Application Publication
(10) Pub. No.: US 2026/0182114 A1
(43) Pub. Date: Jun. 25, 2026

(54) DUAL-SIDED DISPLAY

(71) Applicant: AUO Corporation, Hsinchu City (TW)

(72) Inventors: Ching-Liang Huang, Hsinchu City (TW); Jia-Hong Ye, Hsinchu City (TW); Shu-Hao Huang, Hsinchu City (TW); Sung-Yu Su, Hsinchu City (TW)

(73) Assignee: AUO Corporation, Hsinchu City (TW)

(21) Appl. No.: 19/238,559

(22) Filed: Jun. 16, 2025

(30) Foreign Application Priority Data
Dec. 23, 2024 (TW) 113150133

(51) Int. Cl. H10H 29/45; G09G 3/32; H01L 25/16; H10H 29/37; H10H 29/49; H10H 29/855; H10H 29/856

(52) U.S. Cl. CPC H10H 29/45; G09G 3/32; H10H 29/37; H10H 29/49; H10H 29/8552; H10H 29/856; H10W 90/00; G09G 2360/14

(57) ABSTRACT

A dual-sided display includes a first substrate, a second substrate, a circuit structure, a reflective layer, first pixels, second pixels, and an isolation structure. The second substrate overlaps the first substrate. The circuit structure and the reflective layer are formed above the first substrate and the second substrate respectively. Each first pixel includes a first light emitting diode joined to the circuit structure. The circuit structure is configured to at least partially shield light emitted by the first light emitting diode toward the first substrate. Each second pixel includes a second light emitting diode joined to the circuit structure. The reflective layer is configured to reflect light emitted by the second light emitting diode toward the second substrate. The isolation structure is formed above the second substrate. The first pixels and the second pixels are surrounded by isolation structure.

### CROSS-REFERENCE TO RELATED APPLICATION

This application claims the priority benefit of Taiwan application serial no. 113150133, filed on Dec. 23, 2024. The entirety of the above-mentioned patent application is hereby incorporated by reference herein and made a part of this specification.

### BACKGROUND

### Technical Field

This disclosure relates to a dual-sided display.

### Description of Related Art

Micro-LED display device is a new display technology, utilizing light emitting diodes with dimensions of only a few micrometers as pixel illumination units. Micro-LEDs have characteristics of high brightness, high contrast, low power consumption, and long lifespan, making them very suitable for applications in high resolution displays and wearable devices, and can achieve extremely thin and lightweight designs.

A dual-sided display is a device with two display surfaces, typically used to simultaneously show different content or provide supplementary data on the back side, such as electronic billboards or commercial display screens. This type of display may adopt micro-LED technology, combining its high brightness and low energy consumption characteristics, making it more efficient and durable in dual-sided display applications.

### SUMMARY

The disclosure provides a dual-sided display, capable of efficiently displaying screens on opposite sides.

At least one embodiment of the disclosure provides a dual-sided display, which includes a first substrate, a second substrate, a circuit structure, a reflective layer, multiple first pixels, multiple second pixels, and an isolation structure. The second substrate overlaps with the first substrate. The circuit structure and the reflective layer are formed above the first substrate and the second substrate respectively. Each of the first pixels includes a first light emitting diode joined to the circuit structure. The circuit structure is configured to at least partially shield light emitted from the first light emitting diode toward the first substrate. Each of the second pixels includes a second light emitting diode joined to the circuit structure. The reflective layer is configured to reflect light emitted from the second light emitting diode toward the second substrate. The isolation structure is formed above the second substrate. The first pixels and the second pixels are surrounded by the isolation structure.

At least one embodiment of the disclosure provides a dual-sided display, which includes a circuit structure, a first light emitting diode, and a second light emitting diode. The circuit structure includes a first scan line, a second scan line, a first data line, a second data line, a first light emitting signal line, a second light emitting signal line, a reference voltage signal line, a first work voltage signal line, a second work voltage signal line, a first pixel control circuit, and a second pixel control circuit. The first pixel control circuit includes a first switch transistor, a first drive transistor, a first assist transistor, a first capacitor, and a first illuminate control transistor. A gate of the first switch transistor is electrically connected to the first scan line, and a first source/drain of the first switch transistor is electrically connected to the first data line. A gate of the first assist transistor is electrically connected to the second scan line, and a first source/drain of the first assist transistor is electrically connected to the reference voltage signal line. A first terminal of the first capacitor is electrically connected to a second source/drain of the first assist transistor, a first source/drain of the first drive transistor, and the first work voltage signal line, and a second terminal of the first capacitor is electrically connected to a second source/drain of the first switch transistor and a gate of the first drive transistor. A gate of the first illuminate control transistor is electrically connected to the first light emitting signal line. The second pixel control circuit includes a second switch transistor, a second drive transistor, a second assist transistor, a second capacitor, and a second illuminate control transistor. A gate of the second switch transistor is electrically connected to the first scan line. A first source/drain of the second switch transistor is electrically connected to the second data line. A gate of the second assist transistor is electrically connected to the second scan line. A first source/drain of the second assist transistor is electrically connected to the reference voltage signal line. A first terminal of the second capacitor is electrically connected to a second source/drain of the second assist transistor, the first source/drain of the second drive transistor, and the first work voltage signal line. A second terminal of the second capacitor is electrically connected to a second source/drain of the second switch transistor and a gate of the second drive transistor. A gate of the second illuminate control transistor is electrically connected to the second light emitting signal line. The first light emitting diode is electrically connected to a second source/drain of the first illuminate control transistor and the second work voltage signal line. The second light emitting diode is electrically connected to the second source/drain of the second illuminate control transistor and the second work voltage signal line. The second light emitting diode is configured to illuminate a first side of the dual-sided display, and the first light emitting diode is configured to illuminate a second side of the dual-sided display.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-section schematic diagram of a dual-sided display according to an embodiment of the disclosure.

FIG. 2 is a cross-section schematic diagram of a dual-sided display according to an embodiment of the disclosure.

FIG. 3 is a cross-section schematic diagram of a dual-sided display according to an embodiment of the disclosure.

FIG. 4A to FIG. 4B and FIG. 5A to FIG. 5C are cross-section schematic diagrams of various stages of a manufacturing method of a dual-sided display according to an embodiment of the disclosure.

FIG. 6A is a cross-section schematic diagram of a shield layer according to an embodiment of the disclosure.

FIG. 6B is a relationship diagram between average reflectivity of the shield layer and deposition power of a covering layer according to some embodiments of the disclosure.

FIG. 7 is a bottom perspective schematic diagram of a dual-sided display according to an embodiment of the disclosure.

FIG. 8 is a bottom perspective schematic diagram of a dual-sided display according to an embodiment of the disclosure.

FIG. 9 is a bottom perspective schematic diagram of a dual-sided display according to an embodiment of the disclosure.

FIG. 10 is a bottom perspective schematic diagram of a dual-sided display according to an embodiment of the disclosure.

FIG. 11 is a bottom perspective schematic diagram of a dual-sided display according to an embodiment of the disclosure.

FIG. 12 is an equivalent circuit diagram of a light emitting diode and a pixel control circuit according to an embodiment of the disclosure.

FIG. 13 is a timing diagram of a driving method for a light emitting diode according to an embodiment of the disclosure.

### DESCRIPTION OF THE EMBODIMENTS

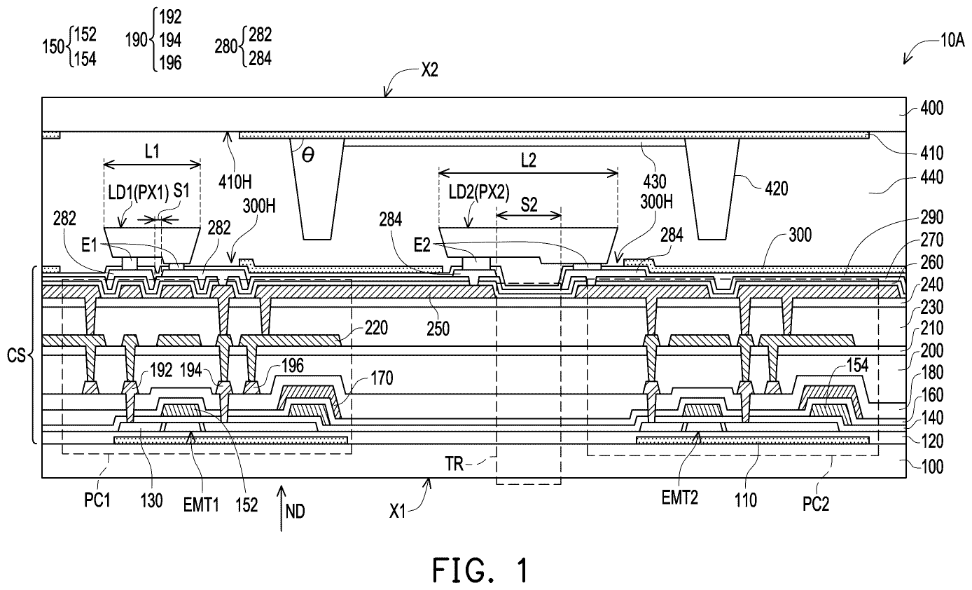

FIG. 1 is a cross-section schematic diagram of a dual-sided display 10A according to an embodiment of the disclosure. Referring to FIG. 1, the dual-sided display 10A includes a first substrate 100, a second substrate 400, a circuit structure CS, a reflective layer 430, multiple first pixels PX1 (FIG. 1 only shows one of them), multiple second pixels PX2 (FIG. 1 only shows one of them), and an isolation structure 420.

The second substrate 400 overlaps with the first substrate 100. The first substrate 100 and the second substrate 400 are transparent substrates, and the material includes glass, organic material or other suitable material. The organic material may exemplify polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU) or other suitable material. The first substrate 100 and the second substrate 400 may be rigid substrates, flexible substrates, or stretchable substrates.

The circuit structure CS is formed above the first substrate 100. The circuit structure CS includes a semiconductor layer, a conductive layer, and an insulation layer, where the number of various layers may be adjusted according to requirements. In this embodiment, the circuit structure CS includes a shield layer 110, a buffer layer 120, a semiconductor layer 130, a gate dielectric layer 140, a first conductive layer 150, a dielectric layer 160, a second conductive layer 170, an interlayer dielectric layer 180, a third conductive layer 190, a first planarization layer 200, a first insulation layer 210, a fourth conductive layer 220, a second planarization layer 230, a second insulation layer 240, a fifth conductive layer 250, a third insulation layer 260, a fourth insulation layer 270, a sixth conductive layer 280, a fifth insulation layer 290, and a first light shading layer 300.

The shield layer 110 is formed above the first substrate 100. In this embodiment, the shield layer 110 directly contacts the first substrate 100, but the disclosure is not limited to this. In other embodiments, there are other insulation layers between the shield layer 110 and the first substrate 100. The shield layer 110 is used to shield ambient light, avoiding ambient light from illuminating the electronic elements in the circuit structure CS and causing interference to the electronic elements. In some embodiments, the material of the shield layer 110 includes metal, metal oxide, or a combination thereof or other suitable material. In some embodiments, the thickness of the shield layer 110 is 900 Å to 8000 Å.

The buffer layer 120 is located above the shield layer 110 and the first substrate 100, and includes insulation material. In some embodiments, the buffer layer 120 may have a single-layer or multi-layer structure.

Multiple semiconductor layers 130 are located on the buffer layer 120. The semiconductor layer 130 has a single-layer or multi-layer structure, and its material includes amorphous silicon, polycrystalline silicon, microcrystalline silicon, single crystal silicon, organic semiconductor material, oxide semiconductor material (for example: indium zinc oxide, indium gallium zinc oxide or other suitable material or a combination of the above materials) or other suitable material or a combination of the above materials. In some embodiments, the semiconductor layer 130 includes a doped region and a channel region, where the doped region may further include a lightly doped region and a heavily doped region. In some embodiments, the semiconductor layer 130 is formed through a low-temperature polycrystalline silicon process.

The gate dielectric layer 140 is located on the semiconductor layer 130. The first conductive layer 150 is located on the gate dielectric layer 140. The first conductive layer 150 includes multiple gates 152 and conductive features 154. Each gate 152 overlaps with the channel region of the corresponding semiconductor layer 130. The conductive features 154 exemplify electrodes, signal lines, or other conductive structures.

The dielectric layer 160 is located on the first conductive layer 150. The second conductive layer 170 is located on the dielectric layer 160. The second conductive layer 170 exemplifies electrodes, signal lines, or other conductive structures.

The interlayer dielectric layer 180 is located on the second conductive layer 170 and the dielectric layer 160. The third conductive layer 190 is located on the interlayer dielectric layer 180. The third conductive layer 190 includes multiple sources/drains 192, 194 and conductive features 196. The sources/drains 192, 194 are electrically connected to the doped regions of the corresponding semiconductor layer 130. The conductive features 196 exemplify electrodes, signal lines, or other conductive structures. In some embodiments, the thickness of the interlayer dielectric layer 180 is 2000 Å to 5000 Å. In some embodiments, the material of the interlayer dielectric layer 180 is silicon nitride or other suitable material.

In this embodiment, one semiconductor layer 130 and its corresponding gate 152 and source/drain 192, 194 constitute a first transistor EMT1 (or called the first illuminate control transistor), while another semiconductor layer 130 and its corresponding gate 152 and source/drain 192, 194 constitute a second transistor EMT2 (or called the second illuminate control transistor).

In this embodiment, the circuit structure CS includes a first pixel control circuit PC1 and a second pixel control circuit PC2, where the first pixel control circuit PC1 includes the first transistor EMT1, and the second pixel control circuit PC2 includes the second transistor EMT2. In some embodiments, the first pixel control circuit PC1 and the second pixel control circuit PC2 may also include other transistors and passive elements (for example, capacitors, resistors, inductors, etc.), and these transistors and passive elements work with each other to drive the light emitting diode.

In this embodiment, the first transistor EMT1 and the second transistor EMT2 are top-gate thin film transistors, but the disclosure is not limited to this. In other embodiments, the first transistor EMT1 and the second transistor EMT2 may include bottom-gate thin film transistors, double-gate thin film transistors, or other types of thin film transistors. In addition, the first pixel control circuit PC1 and the second pixel control circuit PC2 may each include one type or multiple types of transistors.

The shield layer 110 overlaps with the first transistor EMT1 and the second transistor EMT2 in a normal direction ND of the top surface of the first substrate 100, avoiding the problem of leakage current or transistor deterioration caused by ambient light irradiating the semiconductor layer 130 from a first side X1 of the dual-sided display 10A.

The first planarization layer 200 and the first insulation layer 210 are located on the second conductive layer 170 and the interlayer dielectric layer 180, and the first planarization layer 200 and the first insulation layer 210 exemplify different insulation materials.

The fourth conductive layer 220 is located on the first insulation layer 210, and penetrates through the first planarization layer 200 and the first insulation layer 210 and is electrically connected to the third conductive layer 190. In this embodiment, the first insulation layer 210 is only located on the top surface of the first planarization layer 200, but the disclosure is not limited to this. In other embodiments, the first insulation layer 210 may fill in the through hole of the first planarization layer 200, and surround the part of the fourth conductive layer 220 that connects to the third conductive layer 190.

The second planarization layer 230 and the second insulation layer 240 are located on the fourth conductive layer 220 and the first insulation layer 210, and the second planarization layer 230 and the second insulation layer 240 exemplify different insulation materials.

The fifth conductive layer 250 is located on the second insulation layer 240, and penetrates through the second planarization layer 230 and the second insulation layer 240 and is electrically connected to the fourth conductive layer 220. In this embodiment, the second insulation layer 240 is only located on the top surface of the second planarization layer 230, but the disclosure is not limited to this. In other embodiments, the second insulation layer 240 may fill in the through hole of the second planarization layer 230, and surround the part of the fifth conductive layer 250 that connects to the fourth conductive layer 220.

In some embodiments, the thickness of each of the first planarization layer 200 and the second planarization layer 230 is 1 micrometer to 5 micrometers, but the disclosure is not limited to this.

The third insulation layer 260 and the fourth insulation layer 270 are located on the fifth conductive layer 250 and the second insulation layer 240. The sixth conductive layer 280 is located on the fourth insulation layer 270. In some embodiments, the third insulation layer 260 may be omitted.

The sixth conductive layer 280 exemplifies multiple first contact pads 282 and multiple second contact pads 284. In this embodiment, one of the first contact pads 282 is electrically connected to the source/drain 194 of the first transistor EMT1 through the fifth conductive layer 250 and the fourth conductive layer 220, while another first contact pad 282 is electrically connected to a work voltage signal line (or called common signal line), where the work voltage signal line may be located in any one of the first conductive layer 150 to the fourth conductive layer 220. Similarly, one of the second contact pads 284 is electrically connected to the source/drain 194 of the second transistor EMT2 through the fifth conductive layer 250 and the fourth conductive layer 220, while another second contact pad 284 is also electrically connected to the work voltage signal line (or called common signal line).

The fifth insulation layer 290 is located on the sixth conductive layer 280 and the fourth insulation layer 270.

The first light shading layer 300 is located on the fifth insulation layer 290. In some embodiments, the first light shading layer 300 may also be called a black matrix, which has transmittance for visible light that exemplifies less than 1%. The first light shading layer 300 has multiple first openings 300H. The material of the first light shading layer 300 includes metal, metal oxide, black resin or combinations thereof or other suitable materials. In some embodiments, the first light shading layer 300 and the shield layer 110 include the same or different materials.

In this embodiment, the first light shading layer 300 is located on the top surface of the circuit structure CS, but the disclosure is not limited to this. In some embodiments, the first light shading layer 300 may be located between the third insulation layer 260 and the fourth insulation layer 270.

The first pixel PX1 includes a first light emitting diode LD1 joined to the circuit structure CS. Two first electrodes E1 of the first light emitting diode LD1 are joined to the two first contact pads 282 of the circuit structure CS. For example, the first electrode E1 is joined to the first contact pad 282 through solder, conductive adhesive or other conductive connection materials. In some embodiments, the first pixel PX1 includes more than one first light emitting diode LD1, these first light emitting diodes LD1 may be micro light emitting diodes of different colors (such as red micro light emitting diode, green micro light emitting diode and blue micro light emitting diode), so that the dual-sided display 10A has the function of displaying color screens.

The second pixel PX2 includes a second light emitting diode LD2 joined to the circuit structure CS. Two second electrodes E2 of the second light emitting diode LD2 are joined to the two second contact pads 284 of the circuit structure CS. For example, the second electrode E2 is joined to the second contact pad 284 through solder, conductive adhesive or other conductive connection materials. In some embodiments, the second pixel PX2 includes more than one second light emitting diode LD2, these second light emitting diodes LD2 may be micro light emitting diodes of different colors (such as red micro light emitting diode, green micro light emitting diode and blue micro light emitting diode), so that the dual-sided display 10A has the function of displaying color screens.

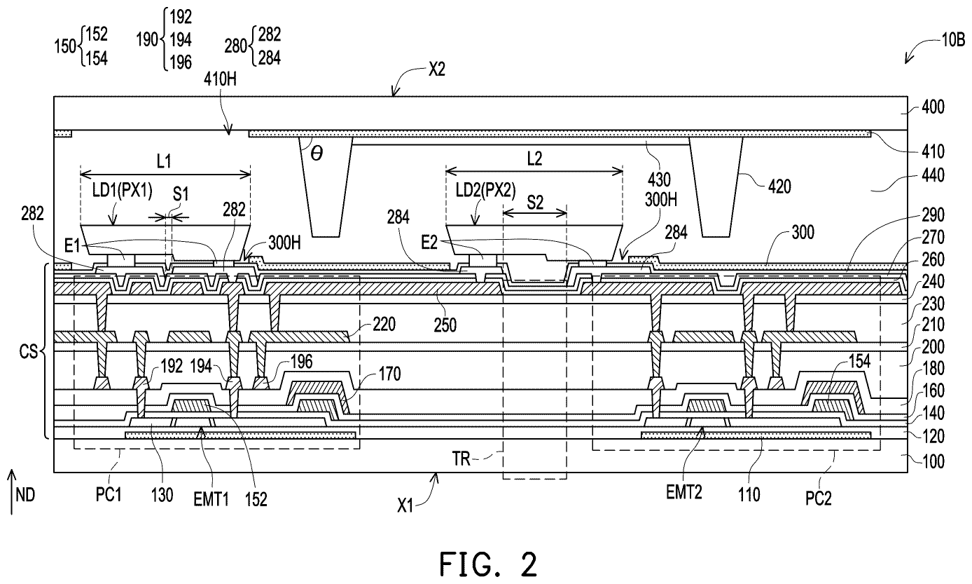

In this embodiment, the first light emitting diode LD1 and the second light emitting diode LD2 may have different dimensions. For example, a length L1 of the first light emitting diode LD1 is different from a length L2 of the second light emitting diode LD2. However, the disclosure is not limited to this. In other embodiments, the first light emitting diode LD1 and the second light emitting diode LD2 may have the same dimensions, as shown in a dual-sided display 10B in FIG. 2. In the dual-sided display 10B, the length L1 of the first light emitting diode LD1 equals the length L2 of the second light emitting diode LD2.

A second light shading layer 410 is formed above the second substrate 400. In this embodiment, the second light shading layer 410 directly contacts the second substrate 400, but the disclosure is not limited to this. In other embodiments, there may also include other insulation layers between the second light shading layer 410 and the second substrate 400. In some embodiments, the second light shading layer 410 may also be called a black matrix, which has transmittance for visible light that exemplifies less than 1%. The second light shading layer 410 has multiple second openings 410H. In some embodiments, the material of the second light shading layer 410 includes metal, metal oxide, black resin or combinations thereof or other suitable materials. In some embodiments, the second light shading layer 410 and the shield layer 110 include the same or different materials.

The isolation structure 420 and the reflective layer 430 are formed above the second substrate 400. In some embodiments, the isolation structure 420 and the reflective layer 430 are located on the second light shading layer 410, wherein the first light shading layer 300 is located between the first substrate 100 and the isolation structure 420, and the second light shading layer 410 is located between the isolation structure 420 and the second substrate 400.

The first pixel PX1 and the second pixel PX2 are surrounded by the isolation structure 420. In some embodiments, the first light emitting diode LD1 in the first pixel PX1 and the second light emitting diode LD2 in the second pixel PX2 are surrounded by the isolation structure 420. The isolation structure 420 laterally isolates the first pixel PX1 and the second pixel PX2, reducing the probability of mutual interference between the first pixel PX1 and the second pixel PX2.

In some embodiments, the isolation structure 420 includes reflective material, and has high reflectivity and low transmittance. In some embodiments, the transmittance of the isolation structure 420 for visible light is less than 10%, and the optical density (OD) of the isolation structure 420 is greater than 1. In some embodiments, an angle θ between the bottom surface and the side surface of the isolation structure 420 is 60 degrees to 90 degrees.

In some embodiments, the material of the reflective layer 430 includes silver, aluminum, or combinations thereof or other suitable materials.

A packaging layer 440 is located between the first substrate 100 and the second substrate 400, and encapsulates the first light emitting diode LD1 and the second light emitting diode LD2. In some embodiments, the packaging layer 440 includes optical adhesive or other suitable materials.

In this embodiment, the first light emitting diode LD1 is configured to illuminate a second side X2 of the dual-sided display 10A, while the circuit structure CS is configured to at least partially shade the light emitted by the first light emitting diode LD1 toward the first substrate 100. For example, one or more light shading structures in the circuit structure CS overlap in the normal direction ND of the top surface of the first substrate 100 with the gap between two first contact pads 282 (marked as a distance S1 between two first contact pads 282 in FIG. 1). The light emitted by the first light emitting diode LD1 toward the first substrate 100 will enter the circuit structure CS through the gap between the two first contact pads 282, and the gap between the two first contact pads 282 is shaded by one or more light shading structures by more than 80% in the normal direction ND, preferably 100% shaded.

In some embodiments, the one or more light shading structures, such as parts of the shield layer 110, semiconductor layer 130, first conductive layer 150, second conductive layer 170, third conductive layer 190, fourth conductive layer 220, fifth conductive layer 250, sixth conductive layer 280 that overlap with the first light emitting diode LD1, may prevent light emitted by the first light emitting diode LD1 from being emitted from the first side X1 of the dual-sided display 10A. The light shading structures are, for example, signal lines, electrodes, or other similar elements in the circuit structure CS.

In this embodiment, the second light emitting diode LD2 is configured to illuminate the first side X1 of the dual-sided display 10A. The reflective layer 430 is configured to reflect the light emitted by the second light emitting diode LD2 toward the second substrate 400. The light emitted by the second light emitting diode LD2 toward the first substrate 100 will enter the circuit structure CS through the gap between two second contact pads 284 (marked as a distance S2 between two second contact pads 284 in FIG. 1), and the gap between the two second contact pads 284 overlaps with a transparent region TR of the circuit structure CS, allowing the light emitted by the second light emitting diode LD2 to be emitted from the first side X1 of the dual-sided display 10A.

In some embodiments, in order to increase the light emitting area of the second light emitting diode LD2 emitting downward, the length L2 of the second light emitting diode LD2 is made greater than the length L1 of the first light emitting diode LD1. Due to the increased length L2, the distance S2 between the two second contact pads 284 may also increase accordingly, thereby enhancing the screen brightness of the first side X1 of the dual-sided display 10A. In some embodiments, the distance S1 between the two first contact pads 282 is smaller than the distance S2 between the two second contact pads 284. In some embodiments, the ratio of the distance S2 between the two second contact pads 284 to the length L2 of the second light emitting diode LD2 is less than 1 and greater than 0.3.

In some embodiments, the first openings 300H of the first light shading layer 300 respectively overlap with the first light emitting diode LD1 and the second light emitting diode LD2. In some embodiments, the dimension of the first opening 300H overlapping with the first light emitting diode LD1 may be the same as or different from the dimension of the first opening 300H overlapping with the second light emitting diode LD2.

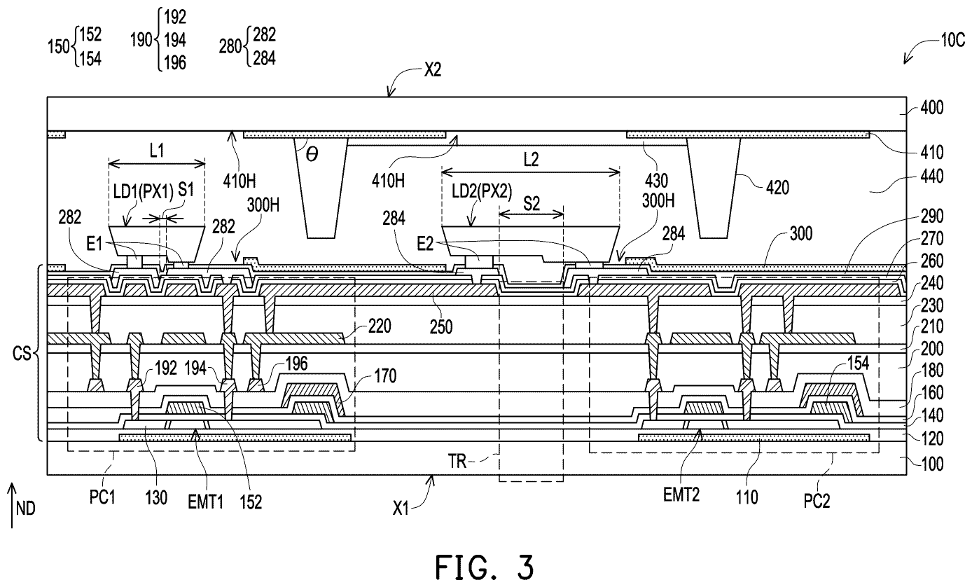

In some embodiments, at least a part of the second openings 410H of the second light shading layer 410 overlaps with the first light emitting diode LD1. In this embodiment, the second opening 410H overlaps with the first light emitting diode LD1, but does not overlap with the second light emitting diode LD2. The second light shading layer 410 extends between the reflective layer 430 and the second substrate 400, and overlaps with the reflective layer 430 and the second light emitting diode LD2. However, the disclosure is not limited to this. In other embodiments, the multiple second openings 410H of the second light shading layer 410 overlap with the first light emitting diode LD1 and the second light emitting diode LD2, as shown in a dual-sided display 10C in FIG. 3. In the dual-sided display 10C, a part of the second openings 410H overlap with the second light emitting diode LD2, and the reflective layer 430 extends into the second opening 410H. In the dual-sided display 10C, the dimension of the second opening 410H overlapping with the first light emitting diode LD1 may be the same as or different from the dimension of the second opening 410H overlapping with the second light emitting diode LD2.

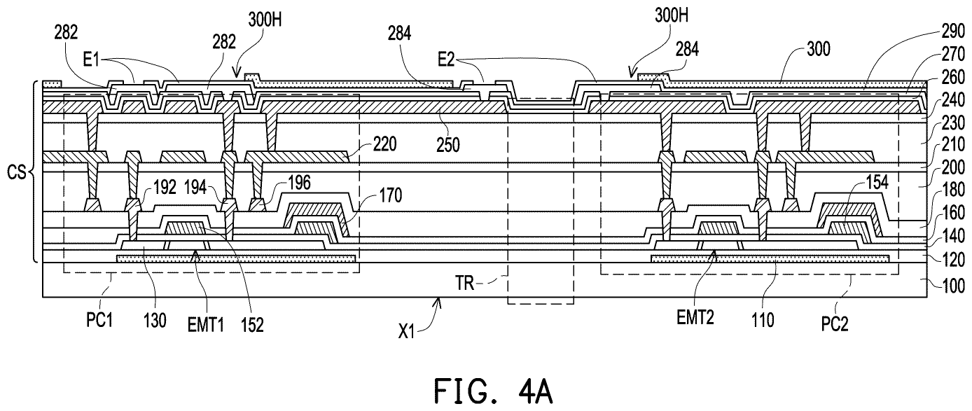

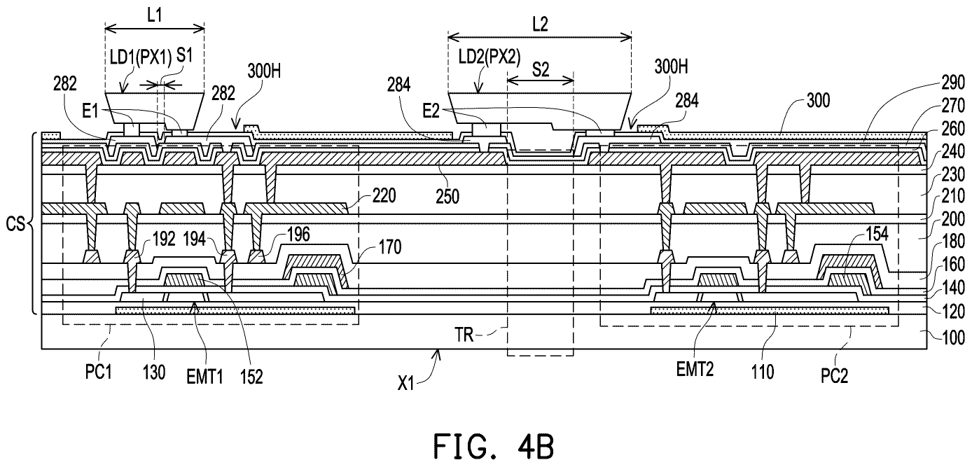

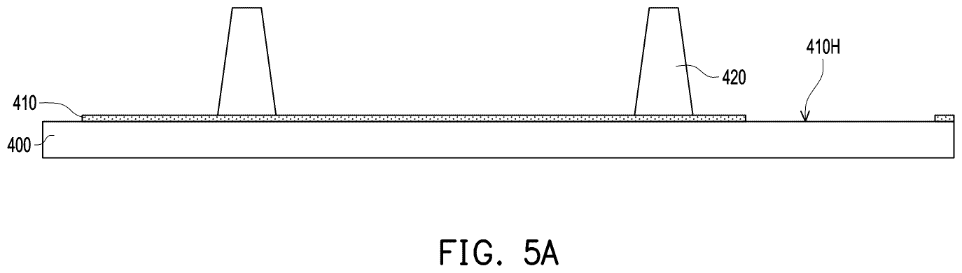

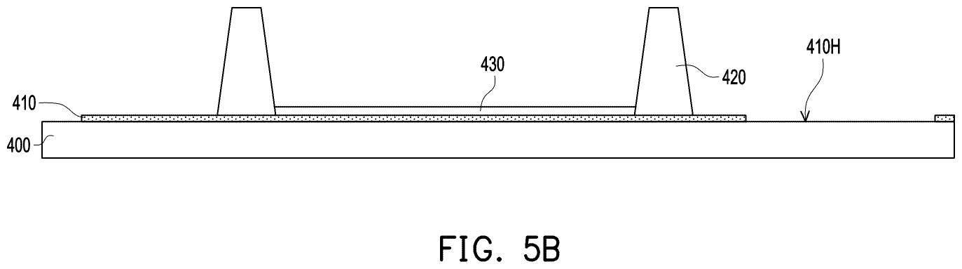

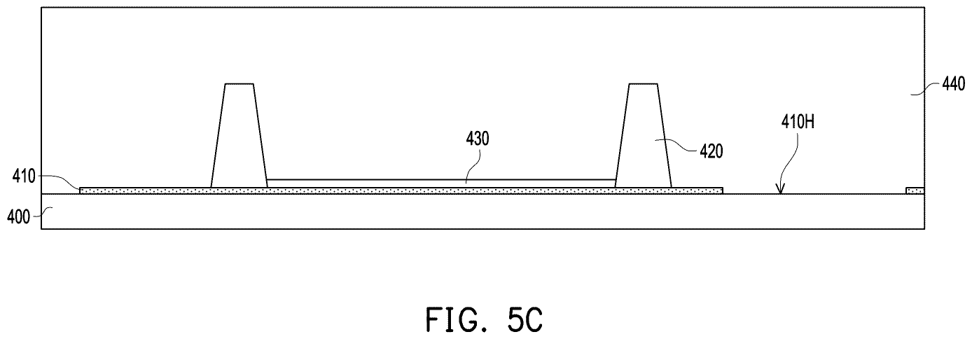

FIG. 4A to FIG. 4B and FIG. 5A to FIG. 5C are cross-section schematic diagrams of various stages of a manufacturing method of the dual-sided display 10A of FIG. 1. FIG. 4A to FIG. 4B show the process on the first substrate 100, while FIG. 5A to FIG. 5C show the process on the second substrate 400.

Referring to FIG. 4A, the circuit structure CS is formed on the first substrate 100.

Referring to FIG. 4B, the first light emitting diode LD1 and the second light emitting diode LD2 are transferred to the circuit structure CS through one or more mass transfer processes.

Referring to FIG. 5A, the second light shading layer 410 is formed on the second substrate 400. For example, the second light shading layer 410 is formed through a printing process or other suitable processes. In some embodiments, a black material layer (for example, metal, oxide, resin, etc.) is coated or deposited on the second substrate 400, then patterned through a photolithography process or etching process to obtain the second light shading layer 410.

After forming the second light shading layer 410, the isolation structure 420 is formed on the second substrate 400. For example, black ink is first applied to the second substrate 400 and the second light shading layer 410, then the isolation structure 420 with high dam height is formed through an imprinting mold or roller imprinting. The imprinting mold may provide greater flexibility to create different geometric appearances to adjust the viewing angle of the dual-sided display.

Then, referring to FIG. 5B, the reflective layer 430 is formed by utilization of inkjet printing or other suitable methods. The reflective layer 430 includes, for example, silver paste or other suitable material.

Referring to FIG. 5C, the packaging layer 440 is formed above the second substrate 400, then the structure shown in FIG. 5C is joined to the structure shown in FIG. 4B by utilization of the packaging layer 440, to obtain the dual-sided display 10A shown in FIG. 1. For example, the structure shown in FIG. 5C is joined to the structure shown in FIG. 4B through a lamination process or other suitable processes.

In some embodiments, after forming the packaging layer 440, a cutting process is performed to cut the structure shown in FIG. 5C to a suitable dimension, but the disclosure is not limited to this.

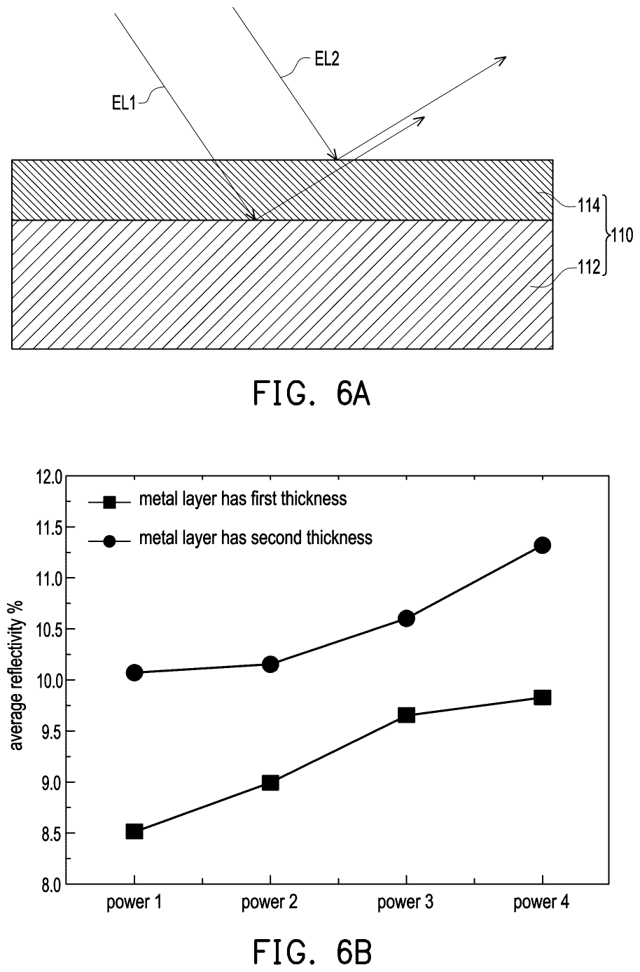

FIG. 6A is a cross-section schematic diagram of a shield layer 110 according to an embodiment of the disclosure. For example, the shield layer 110 in FIG. 1 to FIG. 3 may be replaced by the shield layer 110 of FIG. 6A. Referring to FIG. 6A, the shield layer 110 includes a metal layer 112 and a covering layer 114. The metal layer 112 includes, for example, molybdenum metal or other suitable material, and its thickness is 500 Å to 1500 Å. The covering layer 114 includes, for example, NbSiCOx, CrOx, TiOx, MoOxTa or other suitable material, and its thickness is 300 Å to 800 Å.

The reflected light produced when external environmental light EL1 illuminates the surface of the metal layer 112 and the reflected light produced when external environmental light EL2 illuminates the surface of the covering layer 114 destructively interfere with each other, thereby achieving the purpose of reducing reflected light. In some embodiments, the shield layer 110 is disposed with the covering layer 114 positioned closer to the first substrate 100 (referring to FIG. 1) relative to the metal layer 112, reducing the reflected light produced by external environmental light entering from the first side X1.

Table 1 shows the optical density and average reflectivity of the shield layer 110 obtained by adjusting the material and thickness of the shield layer 110 according to some embodiments.

TABLE 1

| | | | optical | average |
|---|---|---|---|---|
| | material of | | density | reflec- |
| | shield layer | thickness | (OD) | tivity |
| Embodiment 1 | Combination of | 1000 angstroms | 2.3 | 7.1% |
| Embodiment 2 | metal molybdenum | 2000 angstroms | 5.4 | 8.5% |
| Embodiment 3 | and MoOx | 3500 angstroms | 7.2 | 9.2% |
| Embodiment 4 | black resin | about 1 | 4~4.2 | 7.4% |
| | | (micrometer) | | |

FIG. 6B is a relationship diagram between average reflectivity of the shield layer and deposition power of a covering layer according to some embodiments of the disclosure. Referring to FIG. 6A and FIG. 6B, the shield layer 110 includes the metal layer 112 (material is molybdenum) and the covering layer 114 (material is MoOx). In FIG. 6B, the first thickness is less than the second thickness, where the first thickness is 450 Å, and the second thickness is 550 Å.

In the embodiment of FIG. 6B, the covering layer 114 is deposited through a MoOx process, and the average reflectivity of the shield layer 110 is changed by adjusting the deposition power used during the MoOx process. In FIG. 6B, power 1, power 2, power 3, and power 4 increase sequentially.

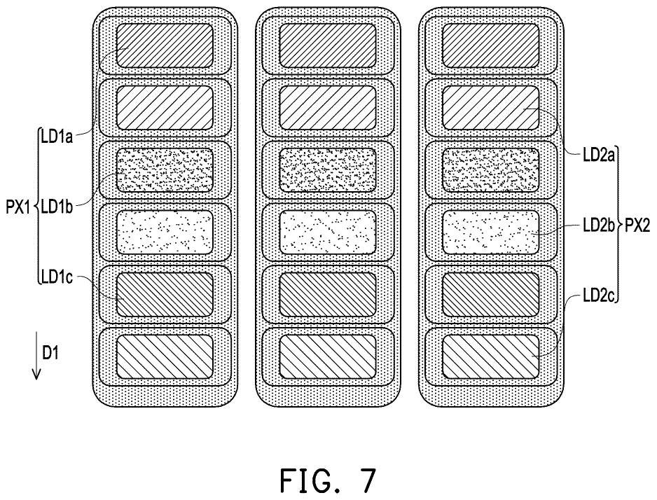

FIG. 7 is a bottom-view perspective schematic diagram of a dual-sided display according to an embodiment of the disclosure. It should be noted that the embodiment of FIG. 7 adopts the reference numerals and part of the content from the embodiment of FIG. 1, where the same or similar reference numerals are used to represent the same or similar elements, and explanations of identical technical content are omitted. For explanations of the omitted parts, please refer to the aforementioned embodiments, which will not be repeated in the following.

Referring to FIG. 7, in this embodiment, the first pixel PX1 includes multiple first light emitting diodes LD1a, LD1b, LD1c. For example, the first light emitting diodes LD1a, LD1b, LD1c are red micro light emitting diodes, green micro light emitting diodes, and blue micro light emitting diodes, respectively.

The second pixel PX2 includes multiple second light emitting diodes LD2a, LD2b, LD2c. For example, the second light emitting diodes LD2a, LD2b, LD2c are red micro light emitting diodes, green micro light emitting diodes, and blue micro light emitting diodes, respectively.

The first light emitting diode LD1a and the second light emitting diode LD2a may be the same or different red micro light emitting diodes. The first light emitting diode LD1b and the second light emitting diode LD2b may be the same or different green micro light emitting diodes. The first light emitting diode LD1c and the second light emitting diode LD2c may be the same or different blue micro light emitting diodes. For example, the first light emitting diode and the corresponding second light emitting diode may be the same or different in dimension, structure and/or main emission wavelength.

In this embodiment, the first light emitting diodes LD1a, LD1b, LD1c are configured to illuminate the second side of the dual-sided display, while the second light emitting diodes LD2a, LD2b, LD2c are configured to illuminate the first side of the dual-sided display. In this embodiment, the light emitting diodes illuminating toward the first side and the light emitting diodes illuminating toward the second side are arranged alternately in the first direction D1.

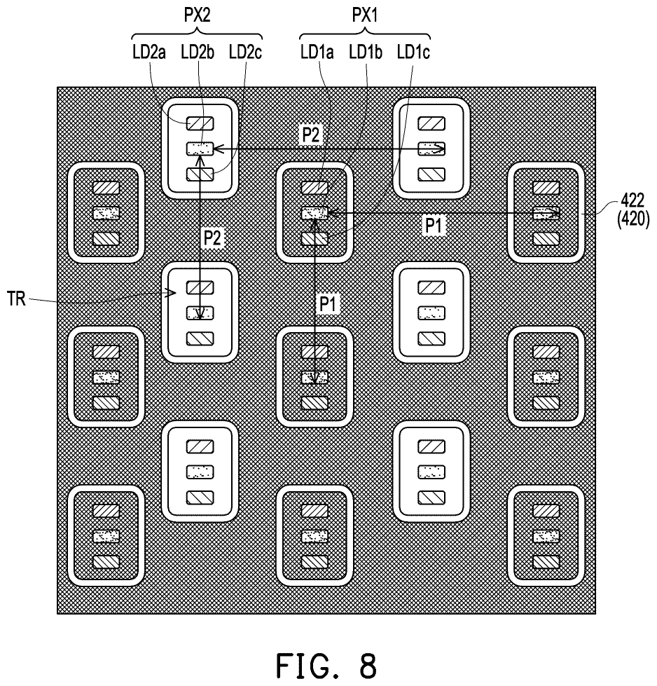

FIG. 8 is a bottom-view perspective schematic diagram of a dual-sided display according to an embodiment of the disclosure. It should be noted that the embodiment of FIG. 8 adopts the reference numerals and part of the content from the embodiment of FIG. 1, where the same or similar reference numerals are used to represent the same or similar elements, and explanations of identical technical content are omitted. For explanations of the omitted parts, please refer to the aforementioned embodiments, which will not be repeated in the following.

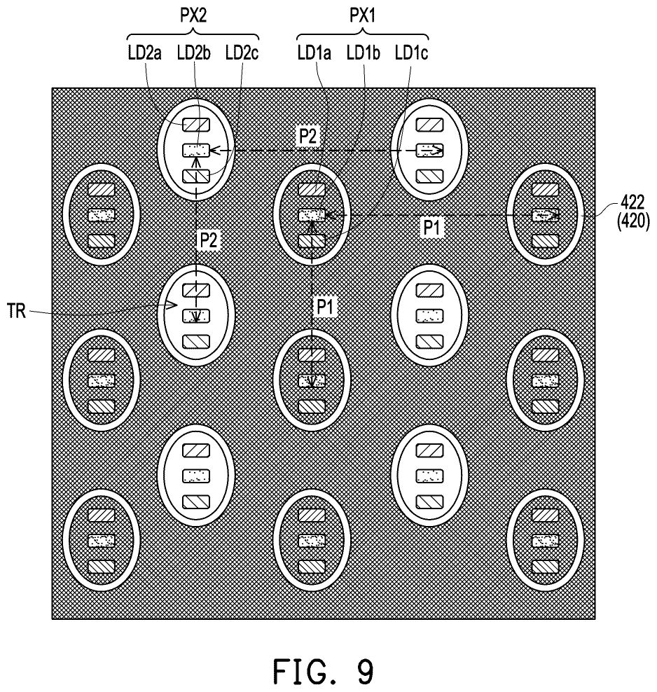

Referring to FIG. 8, in this embodiment, the isolation structure 420 of the dual-sided display includes multiple isolation members 422 that are separated from one another, and each of the first pixel PX1 and the second pixel PX2 is surrounded by a corresponding one of the isolation members 422. In some embodiments, the transmittance of the isolation members 422 for visible light is less than 10%, and the optical density of the isolation members 422 is greater than 1. In FIG. 8, the vertical projection shape of each isolation member 422 is a rounded rectangle, but the disclosure is not limited to this. The vertical projection shape of the isolation members 422 may be circular, rectangular, elliptical (referring to FIG. 9) or other geometric shapes.

In addition, in some embodiments, in the same dual-sided display, the isolation members 422 surrounding the first pixel PX1 and the isolation members 422 surrounding the second pixel PX2 may include different shapes. For example, the vertical projection shape of the isolation members 422 surrounding the first pixel PX1 may be rounded rectangles (as shown in FIG. 7), while the vertical projection shape of the isolation members 422 surrounding the second pixel PX2 may be elliptical (as shown in FIG. 8). By having different shapes for the isolation members 422 surrounding the first pixel PX1 and the isolation members 422 surrounding the second pixel PX2, the viewing angle of the screen on different sides of the dual-sided display may be adjusted.

In FIG. 8, viewing from the first side of the dual-sided display, the light emitted by the first pixel PX1 is shielded by the circuit structure CS, preventing the light emitted by the first pixel PX1 from leaving the dual-sided display from the first side of the dual-sided display. On the other hand, viewing from the first side of the dual-sided display, the second pixel PX2 is exposed by the circuit structure CS, allowing the light emitted by the second pixel PX2 to leave the dual-sided display from the first side of the dual-sided display.

FIG. 8 and FIG. 9 show the transparent region TR of the circuit structure CS, and the circuit structure CS outside the transparent region TR may include one or more of a shield layer, a conductive layer, and a light shading layer.

In this embodiment, multiple second pixels PX2 are configured to display a screen on the first side of the dual-sided display, and multiple first pixels PX1 are configured to display a screen on the second side of the dual-sided display. There is a spacing P2 between the second pixels PX2, and a spacing P1 between the first pixels PX1. In this embodiment, the spacing P2 between the second pixels PX2 equals the spacing P1 between the first pixels PX1, which means the screen displayed on the first side of the dual-sided display and the screen displayed on the second side of the dual-sided display have the same resolution. However, the disclosure is not limited to this. In other embodiments, the spacing P2 between the second pixels PX2 may not equal the spacing P1 between the first pixels PX1, which means the screen displayed on the first side of the dual-sided display and the screen displayed on the second side of the dual-sided display may have different resolutions.

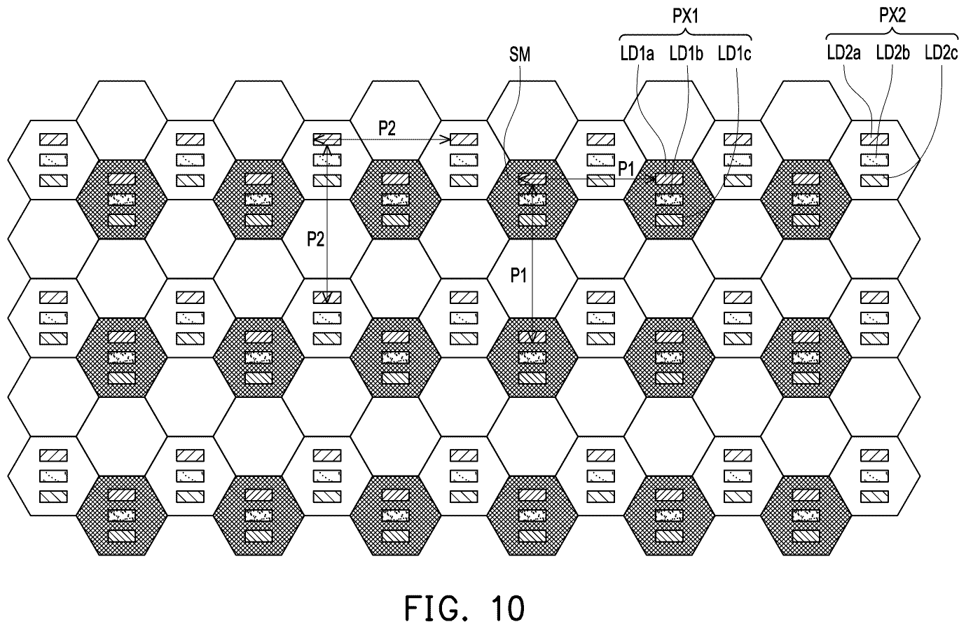

FIG. 10 is a bottom perspective schematic view of a dual-sided display according to an embodiment of the disclosure. It should be noted that the embodiment of FIG. 10 adopts the reference numerals and part of the content from the embodiment of FIG. 1, where the same or similar reference numerals are used to represent the same or similar elements, and the explanation of the same technical content is omitted. For the explanation of the omitted parts, please refer to the aforementioned embodiments, which will not be repeated in the following.

Referring to FIG. 10, in this embodiment, viewing from the first side of the dual-sided display, the first pixel PX1 is shielded by a light shading element SM in the circuit structure, preventing the light emitted by the first pixel PX1 from leaving the dual-sided display from the first side of the dual-sided display. On the other hand, viewing from the first side of the dual-sided display, the second pixel PX2 is exposed by the circuit structure, allowing the light emitted by the second pixel PX2 to leave the dual-sided display from the first side of the dual-sided display.

The light shading element SM of the circuit structure exemplifies a part of one or more of a shield layer, a conductive layer, and a light shading layer. For the shield layer, conductive layer, and light shading layer of the circuit structure CS, please refer to FIG. 1 and related descriptions.

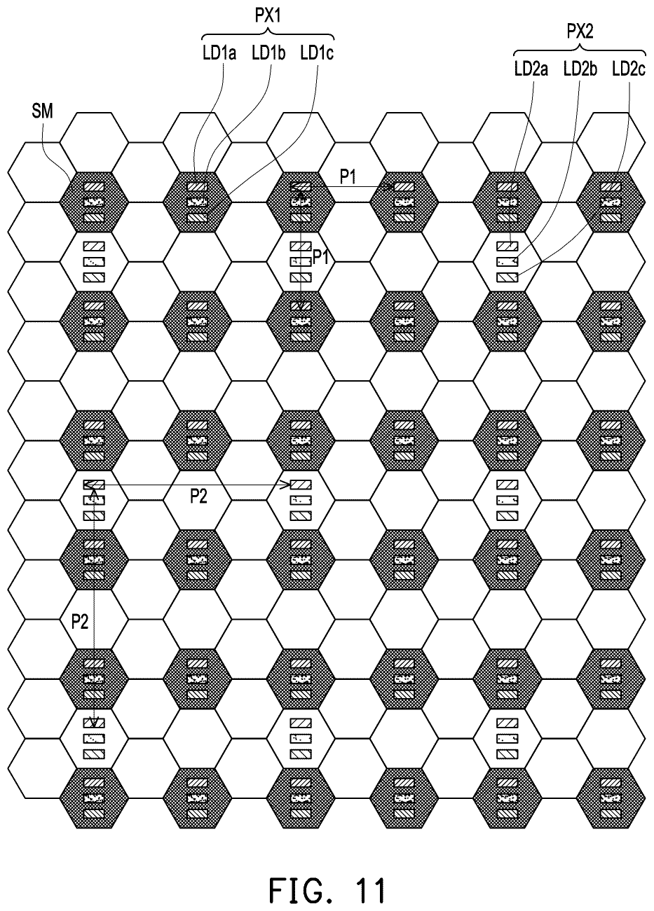

In this embodiment, multiple second pixels PX2 are configured to display a screen on the first side of the dual-sided display, and multiple first pixels PX1 are configured to display a screen on the second side of the dual-sided display. There is a spacing P2 between the second pixels PX2, and a spacing P1 between the first pixels PX1. In this embodiment, the spacing P2 between the second pixels PX2 equals the spacing P1 between the first pixels PX1, which means the screen displayed on the first side of the dual-sided display and the screen displayed on the second side of the dual-sided display may have the same resolution. However, the disclosure is not limited to this. In other embodiments, the spacing P2 between the second pixels PX2 may not equal the spacing P1 between the first pixels PX1, which means the screen displayed on the first side of the dual-sided display and the screen displayed on the second side of the dual-sided display have different resolutions, as shown in FIG. 11.

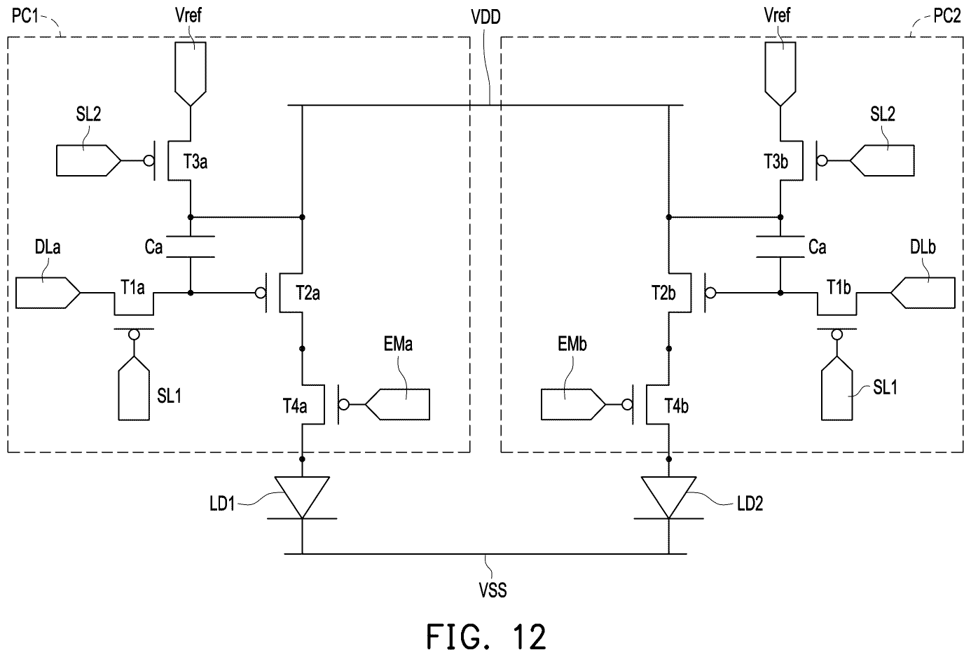

FIG. 12 is an equivalent circuit diagram of a light emitting diode and a pixel control circuit according to an embodiment of the disclosure. It should be noted that the embodiment of FIG. 12 adopts the reference numerals and part of the content from the embodiment of FIG. 1, where the same or similar reference numerals are used to represent the same or similar elements, and the explanation of the same technical content is omitted. For the explanation of the omitted parts, please refer to the aforementioned embodiments, which will not be repeated in the following.

Referring to FIG. 12, in this embodiment, the dual-sided display includes a circuit structure, a first light emitting diode LD1, and a second light emitting diode LD2. In some embodiments, the first light emitting diode LD1 in the first pixel is configured to illuminate the second side of the dual-sided display, and the second light emitting diode LD2 in the second pixel is configured to illuminate the first side of the dual-sided display.

The circuit structure includes a first scan line SL1, a second scan line SL2, a first data line DLa, a second data line DLb, a first light emitting signal line EMa, a second light emitting signal line EMb, a reference voltage signal line Vref, a first work voltage signal line VDD, a second work voltage signal line VSS, a first pixel control circuit PC1, and a second pixel control circuit PC2.

FIG. 12 shows the first pixel control circuit PC1 corresponding to one of the first light emitting diodes LD1 in the dual-sided display and the second pixel control circuit PC2 corresponding to one second light emitting diode LD2 adjacent to the first light emitting diode LD1. The first pixel control circuit PC1 and the second pixel control circuit PC2 are used to drive the first light emitting diode LD1 and the second light emitting diode LD2, respectively. In this embodiment, the first pixel control circuit PC1 and the second pixel control circuit PC2 adjacent to the first pixel control circuit PC1 share the first scan line SL1, the second scan line SL2, the reference voltage signal line Vref, the first work voltage signal line VDD, and the second work voltage signal line VSS. In other words, the first pixel and the second pixel used for displaying screens on different sides share the first scan line SL1, the second scan line SL2, the reference voltage signal line Vref, the first work voltage signal line VDD, and the second work voltage signal line VSS.

The first pixel control circuit PC1 includes a first switch transistor T1a, a first drive transistor T2a, a first assist transistor T3a, a first capacitor Ca, and a first illuminate control transistor T4a. The gate of the first switch transistor T1a electrically connects to the first scan line SL1, and the first source/drain of the first switch transistor T1a electrically connects to the first data line DLa. The gate of the first assist transistor T3a electrically connects to the second scan line SL2, and the first source/drain of the first assist transistor T3a electrically connects to the reference voltage signal line Vref. The first terminal of the first capacitor Ca electrically connects to the second source/drain of the first assist transistor T3a, the first source/drain of the first drive transistor T2a, and the first work voltage signal line VDD, and the second terminal of the first capacitor Ca electrically connects to the second source/drain of the first switch transistor T1a and the gate of the first drive transistor T2a. The gate of the first illuminate control transistor T4a electrically connects to the first light emitting signal line EMa. The first source/drain of the first illuminate control transistor T4a electrically connects to the second source/drain of the first drive transistor T2a.

The first light emitting diode LD1 electrically connects to the second source/drain of the first illuminate control transistor T4a and the second work voltage signal line VSS.

The second pixel control circuit PC2 includes a second switch transistor T1b, a second drive transistor T2b, a second assist transistor T3b, a second capacitor Cb, and a second illuminate control transistor EMb. The gate of the second switch transistor T1b electrically connects to the first scan line SL1. The first source/drain of the second switch transistor T1b electrically connects to the second data line DLb. The gate of the second assist transistor T3b electrically connects to the second scan line SL2. The first source/drain of the second assist transistor T3b electrically connects to the reference voltage signal line Vref. The first terminal of the second capacitor Cb electrically connects to the second source/drain of the second assist transistor T3b, the first source/drain of the second drive transistor T2b, and the first work voltage signal line VDD. The second terminal of the second capacitor Cb electrically connects to the second source/drain of the second switch transistor T1b and the gate of the second drive transistor T2b. The gate of the second illuminate control transistor T4b electrically connects to the second light emitting signal line EMb. The first source/drain of the second illuminate control transistor T4b electrically connects to the second source/drain of the second drive transistor T2b.

The second light emitting diode LD2 electrically connects to the second source/drain of the second illuminate control transistor T4b and the second work voltage signal line VSS.

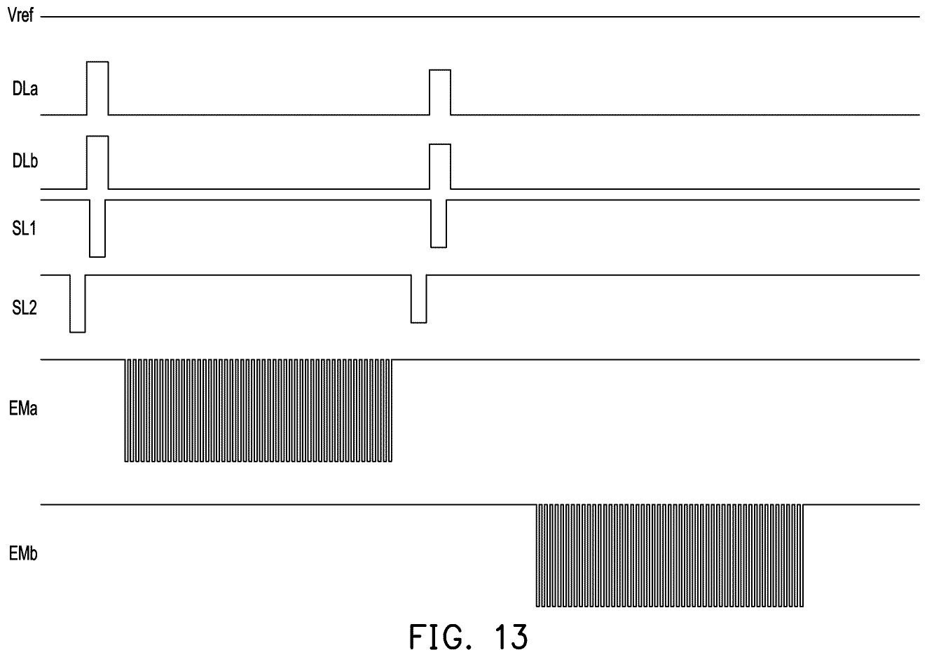

FIG. 13 is a timing diagram of a driving method for a light emitting diode according to an embodiment of the disclosure. Referring to FIG. 12 and FIG. 13 simultaneously, the first pixel control circuit PC1 and the second pixel control circuit PC2 share the first scan line SL1 and the second scan line SL2. However, different first data signal and second data signal may be provided to the first pixel control circuit PC1 and the second pixel control circuit PC2 through the first data line DLa and the second data line DLb respectively, and the first light emitting diode LD1 and the second light emitting diode LD2 may illuminate at different time points through different first light emitting signal line EMa and second illuminate control transistor EMb.

As shown in FIG. 13, first, a signal (for example, called a reset signal) is provided to the first assist transistor T3a and the second assist transistor T3b by utilization of the second scan line SL2.

Next, the first switch transistor T1a and the second switch transistor T1b are turned on by utilization of the first scan line SL1, and the first data signal and the second data signal are written into the first pixel control circuit PC1 and the second pixel control circuit PC2 respectively by utilization of the first data line DLa and the second data line DLb.

Then, the first illuminate control transistor T4a is turned on by utilization of the first light emitting signal line EMa to illuminate the first light emitting diode LD1. At this time, the second illuminate control transistor T4b maintains a closed state.

Next, a signal (for example, called a reset signal) is again provided to the first assist transistor T3a and the second assist transistor T3b by utilization of the second scan line SL2.

Next, the first switch transistor T1a and the second switch transistor T1b are again turned on by utilization of the first scan line SL1, and the first data signal and the second data signal are written into the first pixel control circuit PC1 and the second pixel control circuit PC2 respectively by utilization of the first data line DLa and the second data line DLb.

Finally, the second illuminate control transistor T4b is turned on by utilization of the second light emitting signal line EMb to illuminate the second light emitting diode LD2. At this time, the first illuminate control transistor T4a maintains a closed state.

Through the above method, the first light emitting diode LD1 and the second light emitting diode LD2 may be illuminated sequentially.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A dual-sided display, comprising:
a first substrate and a second substrate overlapping with the first substrate;
a circuit structure and a reflective layer, formed above the first substrate and the second substrate respectively;
a plurality of first pixels, each of the first pixels comprising:
a first light emitting diode, joined to the circuit structure, wherein the circuit structure is configured to at least partially shield light emitted by the first light emitting diode toward the first substrate;
a plurality of second pixels, each of the second pixels comprising:
a second light emitting diode, joined to the circuit structure, wherein the reflective layer is configured to reflect light emitted by the second light emitting diode toward the second substrate; and
an isolation structure, formed above the second substrate, wherein the first pixels and the second pixels are surrounded by the isolation structure.

2. The dual-sided display according to claim 1, wherein the first light emitting diode is joined to two first contact pads of the circuit structure, and the second light emitting diode is joined to two second contact pads of the circuit structure, wherein one or more light shading structures in the circuit structure overlap with a gap between the two first contact pads in a normal direction of a top surface of the first substrate, and a gap between the two second contact pads overlaps with a transparent region of the circuit structure.

3. The dual-sided display according to claim 1, wherein the isolation structure comprises a plurality of isolation members separated from each other, and the each of the first pixels and the each of the second pixels is surrounded by a corresponding one of the isolation members, wherein transmittance of the isolation structure for visible light is less than 10%, and optical density of the isolation structure is greater than 1.

4. The dual-sided display according to claim 1, wherein the circuit structure comprises a first light shading layer, the first light shading layer is located between the first substrate and the isolation structure and has a plurality of first openings, the first openings respectively overlap with the first light emitting diode and the second light emitting diode; and the dual-sided display further comprising:
a second light shading layer, located between the isolation structure and the second substrate, and having a plurality of second openings, at least a part of the second openings overlapping with the first light emitting diode.

5. The dual-sided display according to claim 4, wherein the light shading layer extends between the reflective layer and the second substrate, and the light shading layer overlaps with the reflective layer and the second light emitting diode.

6. The dual-sided display according to claim 1, wherein a spacing between the first pixels is different from a spacing between the second pixels.

7. The dual-sided display according to claim 1, wherein the first light emitting diode is joined to two first contact pads of the circuit structure, and the second light emitting diode is joined to two second contact pads of the circuit structure, wherein a distance between the two first contact pads is less than a distance between the two second contact pads.

8. The dual-sided display according to claim 1, wherein the first light emitting diode is joined to two first contact pads of the circuit structure, and the second light emitting diode is joined to two second contact pads of the circuit structure, wherein a ratio of a distance between the two second contact pads to a length of the second light emitting diode is less than 1 and greater than 0.3.

9. A dual-sided display, comprising:
a circuit structure, comprising
a first scan line and a second scan line;
a first data line and a second data line;
a first light emitting signal line and a second light emitting signal line;
a reference voltage signal line, a first work voltage signal line, and a second work voltage signal line;
a first pixel control circuit, comprising:
a first switch transistor, wherein a gate of the first switch transistor is electrically connected to the first scan line, and a first source/drain of the first switch transistor is electrically connected to the first data line;
a first drive transistor;
a first assist transistor, wherein a gate of the first assist transistor is electrically connected to the second scan line, and a first source/drain of the first assist transistor is electrically connected to the reference voltage signal line;
a first capacitor, wherein a first terminal of the first capacitor is electrically connected to a second source/drain of the first assist transistor, a first source/drain of the first drive transistor, and the first work voltage signal line, and a second terminal of the first capacitor is electrically connected to a second source/drain of the first switch transistor and a gate of the first drive transistor;
a first illuminate control transistor, wherein a gate of the first illuminate control transistor is electrically connected to the first light emitting signal line, and a first source/drain of the first illuminate control transistor is electrically connected to a second source/drain of the first drive transistor; and
a second pixel control circuit, comprising:
a second switch transistor, wherein a gate of the second switch transistor is electrically connected to the first scan line, and a first source/drain of the second switch transistor is electrically connected to the second data line;
a second drive transistor;
a second assist transistor, wherein a gate of the second assist transistor is electrically connected to the second scan line, and a first source/drain of the second assist transistor is electrically connected to the reference voltage signal line;
a second capacitor, wherein a first terminal of the second capacitor is electrically connected to a second source/drain of the second assist transistor, the first source/drain of the second drive transistor, and the first work voltage signal line, and a second terminal of the second capacitor is electrically connected to a second source/drain of the second switch transistor and a gate of the second drive transistor;
a second illuminate control transistor, wherein a gate of the second illuminate control transistor is electrically connected to the second light emitting signal line, and a first source/drain of the second illuminate control transistor is electrically connected to a second source/drain of the second drive transistor;
a first light emitting diode, electrically connected to a second source/drain of the first illuminate control transistor and the second work voltage signal line; and
a second light emitting diode, electrically connected to the second source/drain of the second illuminate control transistor and the second work voltage signal line, wherein the second light emitting diode is configured to illuminate a first side of the dual-sided display, and the first light emitting diode is configured to illuminate a second side of the dual-sided display.

10. The dual-sided display according to claim 9, further comprising:
a first substrate and a second substrate overlapping with the first substrate, wherein the circuit structure is formed on the first substrate, wherein the circuit structure is configured to at least partially shield light emitted by the first light emitting diode toward the first substrate;
a reflective layer, formed on the second substrate, wherein the reflective layer is configured to reflect light emitted by the second light emitting diode toward the second substrate; and
an isolation structure, formed on the second substrate, wherein the first light emitting diode and the second light emitting diode are surrounded by the isolation structure.

11. The dual-sided display according to claim 10, wherein the circuit structure comprises a first light shading layer, the first light shading layer is located between the first substrate and the isolation structure and has a plurality of first openings, the first openings respectively overlap with the first light emitting diode and the second light emitting diode; and the dual-sided display further comprising:
a second light shading layer, located between the isolation structure and the second substrate, and having a plurality of second openings, at least a part of the second openings overlapping with the first light emitting diode.

12. The dual-sided display according to claim 10, wherein transmittance of the isolation structure for visible light is less than 10%, and optical density of the isolation structure is greater than 1.

13. The dual-sided display according to claim 9, wherein the first light emitting diode is joined to two first contact pads of the circuit structure, and the second light emitting diode is joined to two second contact pads of the circuit structure, wherein a gap between the two second contact pads overlaps with a transparent region of the circuit structure.

14. The dual-sided display according to claim 13, wherein a ratio of a distance between the two second contact pads to a length of the second light emitting diode is less than 1 and greater than 0.3.

15. The dual-sided display according to claim 13, wherein a distance between the two first contact pads is less than a distance between the two second contact pads.
